(19) United States
(12) Patent Application Publication
(10) Pub. No.: US 2009/0108885 A1
(43) Pub. Date: Apr. 30, 2009

(54) Design structure for CMOS differential rail-to-rail latch circuits

(75) Inventors: Joseph Natonio, Wappingers Falls, NY (US); Steven J. Zier, Hopewell Junction, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: International Business Machines Corporation

(21) Appl. No.: 11/982,206

(22) Filed: Oct. 31, 2007

(51) Int. Cl. H03K 3/3562; H03K 21/00; H03K 3/00

(52) U.S. Cl. 327/115; 327/202; 327/215

(57) ABSTRACT

A design structure including a CMOS rail-to-rail differential latch is provided in which a plurality of cross-coupled devices pull first and second nodes of the latch to opposite rail-to-rail voltages. Desirably, first and second output isolating elements have inputs coupled to the first and second nodes, the output isolating elements being operable to output versions of the opposite rail-to-rail voltages as a true and a complementary output of the latch. In this way, the true output has a rising edge occurring simultaneously with a falling edge of the complementary output. The complementary output has a rising edge occurring simultaneously with a falling edge of the true output. First and second input isolating elements of the latch have outputs coupled to the first and second nodes, the first and second input isolating elements being operable to apply versions of input signals to the first and second nodes.

### BACKGROUND OF THE INVENTION

The present invention relates to complementary metal oxide semiconductor circuits, and more specifically to latch circuits, flip-flops and clock divider circuits.

FIG. 1 is a block and schematic diagram illustrating the structure of a master-slave “D-type” flip-flop 10 in accordance with the prior art. Flip-flop 10 includes a first latch or “master” latch 12 formed by cross-coupled inverters 12A and 12B. Through an inverter 24, the master latch 12 is coupled to an input of a second latch or “slave” latch 14, the slave latch being formed by cross-coupled inverters 14A and 14B. The flip-flop 10 is clocked via a complementary clock signal pair (indicated as true clock signal C and complementary clock signal /C) applied to transmission gates 16, 18, 20, and 22. The flip-flop 10 accepts a single-ended data signal at the “D” input thereto. Once latched by the master latch 12 on the falling edge of the true clock signal C, the latched state of the data signal is transferred through an inverter 24 to the slave latch 14 on the rising edge of the true clock signal.

One problem with the flip-flop shown in FIG. 1A is lack of synchronism between the true output Q of the latch and the complementary output /Q. The latched state of the slave latch 14 provides the complementary output /Q of the flip-flop 10 directly. On the other hand, the true output Q of the flip-flop is generated by inverting the complementary output /Q by an inverter 26. As the operation of the inverter 26 is not instantaneous, the true output Q is delayed in relation to the complementary output /Q. As a result, the edges of the true and complementary outputs Q and /Q are not synchronized. Referring to FIG. 1B, the rising edge 60 of the Q output is delayed by the delay of inverter 26 such that the rising edge 60 occurs after the falling edge 62 of the /Q output. In addition, the falling edge 70 of the Q output is also delayed by the delay of inverter 26 such that the falling edge 70 occurs after the rising edge 72 of the /Q output.

The transmission of signals by simultaneously swinging differential (true and complementary) signals can improve signal-to-noise ratio (“SNR”). Differential signals (e.g., signals IN and /IN; FIG. 1C) typically are inputted to a current mode logic (“CML”) circuit 36, e.g., a differential amplifier. In such CML circuit 36, a pair of input devices (n-type MOS devices) 30, 32 have source terminals connected to the drain of a tail device 34, which is biased by a voltage VB for conducting a constant current. The CML circuit produces the differential outputs OUT and /OUT. The outputs swing simultaneously in opposite directions between low and high voltage levels.

For a variety of reasons, differential signals are not normally handled by traditional CMOS devices. CMOS devices, as exemplified by the CMOS inverter 40 shown in FIG. 1D, typically include a p-type MOS device 42 having a drain tied to the drain of an n-type MOS device 44 at an output OUT of the circuit. The pMOS device 42 further has a gate tied to the gate of the nMOS device 44, and the input signal IN is applied to the gates of the nMOS and pMOS devices simultaneously. CML circuits typically have different device designs and operating parameters than CMOS devices.

The delay between the transitions of the /Q output and the Q output of the flip-flop 10 make them not suitable for input to a differential logic circuit, i.e., a digital logic circuit which requires differential input signals, i.e., true and complementary input signals which simultaneously swing between opposite levels. When inputted to a differential logic circuit, the delay between the edges of the output signals Q and /Q could cause an indeterminate state or latch-up to occur. For this reason, the flip-flop shown in FIG. 1A is not considered a good circuit for use in connection with a differential logic circuit.

### SUMMARY OF THE INVENTION

In accordance with one aspect of the invention, a design structure including a CMOS rail-to-rail differential latch is provided in which a plurality of cross-coupled devices pull first and second nodes of the latch to opposite rail-to-rail voltages. Desirably, the latch includes first and second output isolating elements which have inputs coupled to the first and second nodes, the output isolating elements being operable to output versions of the opposite rail-to-rail voltages as a true and a complementary output of the latch. In this way, the true output has a rising edge occurring simultaneously with a falling edge of the complementary output. The complementary output has a rising edge occurring simultaneously with a falling edge of the true output. Desirably, the latch also includes first and second input isolating elements which have outputs coupled to the first and second nodes, the first and second input isolating elements being operable to apply versions of input signals to the first and second nodes.

In accordance with another aspect of the invention, a design structure including a master-slave (“MS”) CMOS differential rail-to-rail flip-flop is provided which includes one or more instances of the CMOS differential rail-to-rail latch. In addition, a MS CMOS single-ended to differential flip-flop is provided which accepts a single-ended input signal and provides true and complementary output signals. A clock divider circuit can be provided which incorporates the MS CMOS single-ended to differential flip-flop.

Furthermore, in a differential clock divider circuit, the true and complementary outputs of a MS CMOS differential flip-flop are applied as feedback to the inputs of that flip-flop. In this way, the outputs of the flip-flop transition at a frequency which is divided down in relation to the frequency of a differential clock signal applied thereto. A single-ended to differential clock divider circuit, based upon the MS CMOS differential flip-flop, accepts a single-ended input signal and produces true and complementary output signals which represent versions of a differential clock signal divided down in frequency from that of the differential clock signal.

### BRIEF DESCRIPTION OF THE DRAWINGS

FIG. 1A illustrates a flip-flop in accordance with the prior art.

FIG. 1B is a timing diagram illustrating operation of the flip-flop depicted in FIG. 1A.

FIG. 1C illustrates a CML circuit in accordance with the prior art.

FIG. 1D illustrates a CMOS inverter in accordance with the prior art.

FIG. 2A illustrates a differential rail-to-rail latch in accordance with one embodiment of the invention.

FIG. 2B illustrates a circuit arrangement including a portion of the latch illustrated in FIG. 2A.

FIG. 2C is a timing diagram illustrating operation of the latch depicted in FIG. 2A.

FIG. 3 illustrates a differential rail-to-rail master-slave flip-flop in accordance with one embodiment of the invention.

FIG. 4 illustrates a single-ended to differential rail-to-rail master-slave flip-flop in accordance with one embodiment of the invention.

FIG. 5 illustrates a differential rail-to-rail clock converter circuit in accordance with a variation of the embodiment of the invention depicted in FIG. 4.

FIG. 6 illustrates a differential rail-to-rail clock converter circuit in accordance with a variation of the embodiment of the invention depicted in FIG. 3.

FIG. 7 illustrates a differential rail-to-rail clock converter circuit in accordance with a variation of the embodiment of the invention depicted in FIG. 6.

FIG. 8 illustrates a further differential rail-to-rail clock converter circuit in accordance with a variation of the embodiment of the invention depicted in FIG. 7.

FIG. 9 is a block diagram of an exemplary design flow such as can be used in fabrication of a design structure in accordance with an embodiment of the present invention.

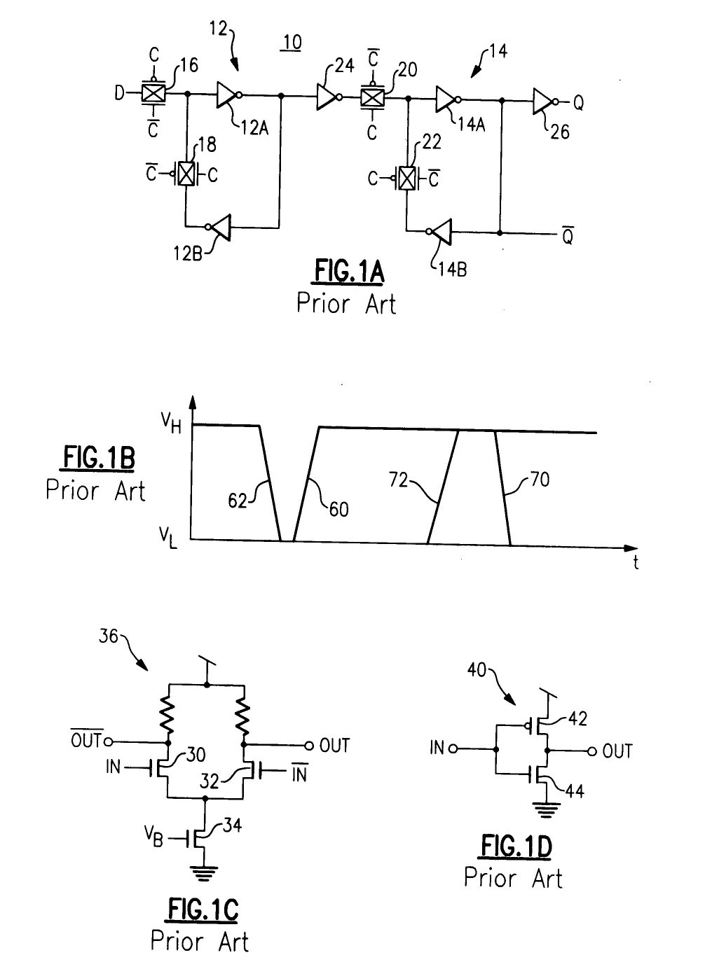

### DETAILED DESCRIPTION

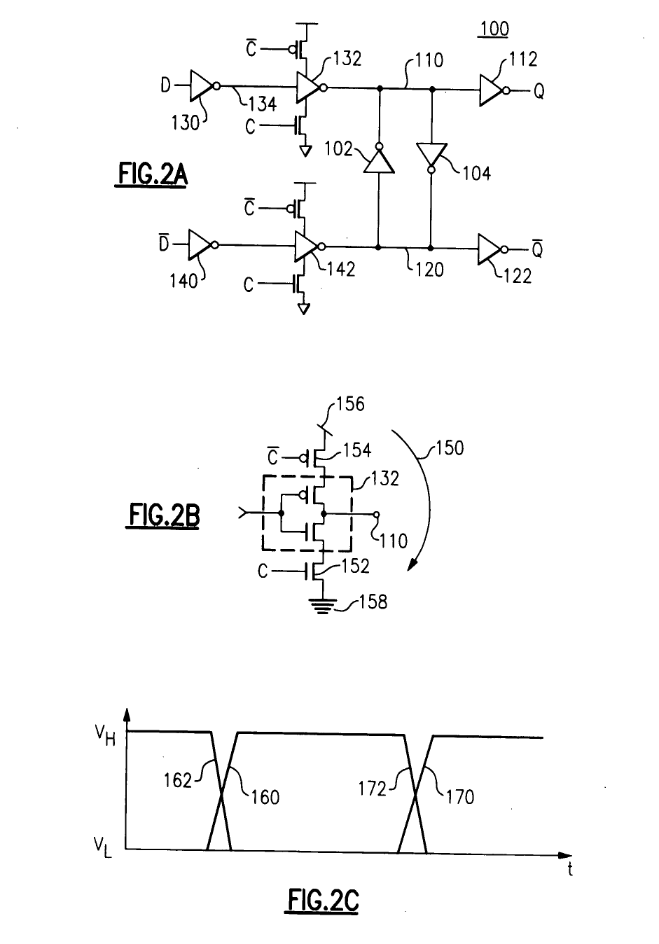

Commonly owned U.S. patent application Ser. No. 11/668,137 filed Jan. 29, 2007 to Joseph Natonio et al. entitled “CMOS Differential Rail-to-Rail Latch Circuits” is incorporated by reference herein. FIG. 2A illustrates a differential CMOS latch in accordance with a first embodiment of the invention. As a CMOS circuit, the latch includes a pair of cross-coupled CMOS inverters 102, 104, which serve to maintain the logic states of a first node 110 and a second node 120 at rail-to-rail logic levels. With rail-to-rail logic levels, the high logic state is represented by a steady state voltage which usually is the same as a voltage level at which power is supplied to the source terminal of the pMOS device of each cross-coupled inverter in the latch. The low logic state usually is represented by ground, the voltage to which the source terminal of the nMOS device of each cross-coupled inverter of the latch is connected. By the action of the cross-coupled CMOS inverters 102, 104, when the first node 110 is at the high logic state the second node 120 will be at the low logic state. The first and second nodes 110, 120 transition simultaneously between logic states such that when the first node 110 transitions to the low logic state, the second node 120 transitions simultaneously to the high logic state. Conversely, when the first node 110 transitions to the high logic state, the second node 120 transitions simultaneously to the low logic state.

The latch accepts a differential signal pair as input, the differential signal pair including a “true” input signal D and a “complementary” input signal /D. The complementary input signal swings simultaneously with the true input signal, but in the opposite direction as the true input signal. Ahead of the first node 110, in a first leg of the latch, inverters 130, 132 serve to isolate the logic state of the first node 110 from the “true” input signal “D”. As best seen in FIG. 2B, inverter 132 is arranged in a current path 150 between a source of a power supply voltage 156 and ground 158. For timing the operation of the latch, an nMOS device 152 and a pMOS device 154 are activated by a differential clock signal pair. The differential clock signal pair includes a true clock signal (“C”) and a complementary clock signal (“/C”). The complementary clock signal /C is the same as the true clock signal, but is one half clock cycle out of phase with respect to the true clock signal such that the complementary clock signal swings simultaneously in the opposite direction as the true clock signal. With this arrangement, when the state of the D signal at the input to inverter 130 is low, such that the output 134 of inverter 130 is high, the rising edge of the true clock signal C times the operation of the inverter 132 to transition from high logic state to low logic state. Conversely, when the state of the D signal input to inverter 130 is high and the output 134 is low, the rising edge of the true clock signal C times the operation of the inverter 132 to transition from low logic state to high logic state.

Similar to that described above, in a second leg of the latch 100, inverters 140, 142 serve to isolate the logic state of the second node 120 from the complementary input signal /D. Again, the rising edge of the true clock signal C times the operation of inverter 142 to apply the complementary input signal /D to the second node 120 at the same time that the true input signal D is applied to the first node.

As further shown in FIG. 2A, the first node 110 is coupled to a first output isolating element, being, for example, an inverter 112. Inverter 112 isolates the first node 110 from the output signal Q of the latch, the inverter 112 sourcing and sinking sufficient current to drive the output signal Q in accordance with the needs of a circuit (not shown) which receives that signal (Q). In like manner, inverter 122 isolates the second node 120 from the complementary output /Q of the latch. Inverter 122 sources and sinks sufficient current to drive the output signal /Q in accordance with the needs of a circuit (not shown) which receives that signal (/Q).

In this way, the true and complementary output signals Q and /Q are each output by the same number of isolating elements following the first and second nodes. In the example illustrated in FIG. 2A, one inverter 112 functions as an element which isolates output Q from the first node 110. Likewise, one inverter 122 functions as an element which isolates output /Q from the second node 120. In addition, each isolating element (each inverter 112 or 122) delays the respective output signal Q or /Q by the same amount as the other isolating element. As a result, the output signals Q and /Q of the latch 100 are synchronized in that they transition simultaneously between low and high logic states. Specifically, as illustrated in FIG. 2C, the rising edge 160 of the true output signal Q (to the high level V_{H}) occurs simultaneously with the falling edge 162 of the complementary output signal /Q to the low level V_{L}, these edges 160, 162 being timed in relation to the rising edge of the true clock signal C. Likewise, the falling edge 172 of the true output signal Q occurs simultaneously with the rising edge 170 of the complementary output signal /Q. Again, these edges 170, 172 are timed in relation to the rising edge of the true clock signal C. In such way, the CMOS differential latch 100 illustrated in FIG. 2A provides true and complementary output signals Q and /Q which transition simultaneously, making the CMOS latch 100 suitable for supplying differential rail-to-rail signals for input to differential logic circuits. However, the differential CMOS latch 100 does not function as an “edge-triggered” latch. Stated another way, during the half cycle of the differential clock when C and /C are active, change in the D and /D input signals can cause the states of the first and second nodes and the true and complementary output signals to change.

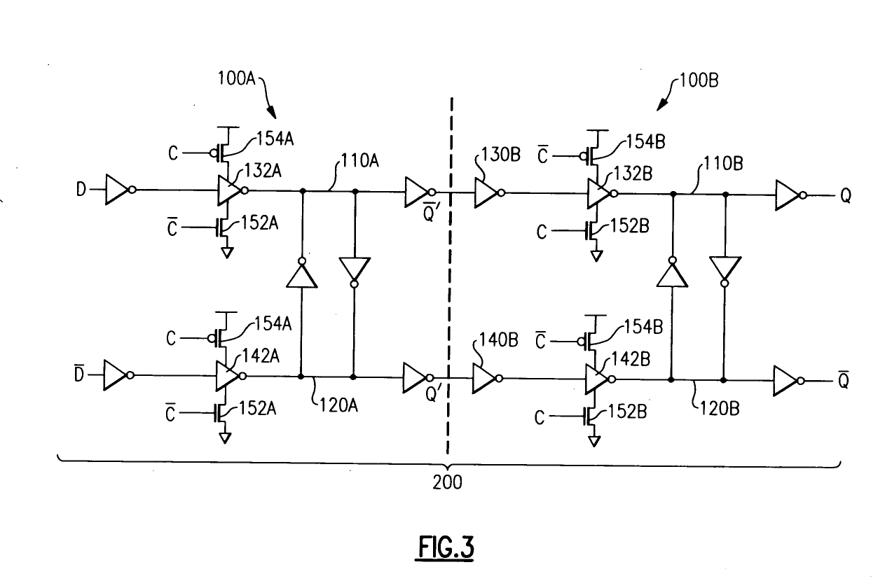

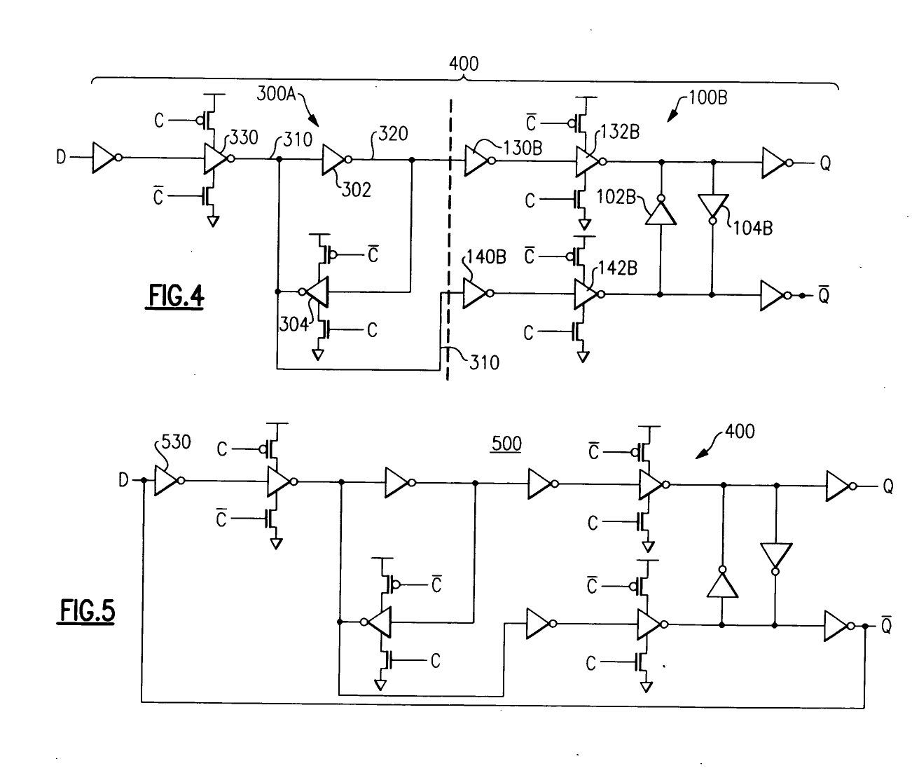

FIG. 3 illustrates an edge-triggered master-slave (“MS”) flip-flop 200 in accordance with a second embodiment of the invention. The MS flip-flop includes two rail-to-rail differential CMOS latches 100A, 100B (FIGS. 2A-2C), arranged in series, such that the output signals /Q′ and Q′ of the first latch 100A are applied to the inputs of inverters 130B and 140B of the second latch 100B. As in the case of the differential CMOS latch 100, the output signals Q and /Q are differential signals, i.e., simultaneously swinging true and complementary signals with rail-to-rail signal levels.

In the MS flip-flop, inverters 132B and 142B of the second latch 100B are timed differently from the inverters 132A and 142A of the first latch 100A. In this case, the complementary clock signal /C is applied to the pMOS devices 154B, and the true clock signal C is applied to the nMOS devices 152B. On the other hand, in the first (master) latch 100A, the true clock signal C is applied to the pMOS devices 154A, and the complementary clock signal /C is applied to the nMOS devices 152A. With this clocking arrangement, signals are latched to the first and second nodes 110B, 120B of the second (slave) latch one half cycle of the differential clock later than they are latched to the first and second nodes 110A, 120A of the first latch. In addition, the slave latch 100B receives the latched output signals of the master latch as input signals and the inverters 132B and 142B are timed to transition one half cycle of the differential clock later than the inverters 132A and 132B. As a result, the final output signals Q and /Q of the MS flip-flop are edge-triggered such that they transition only at the rising edge of the true clock signal C.

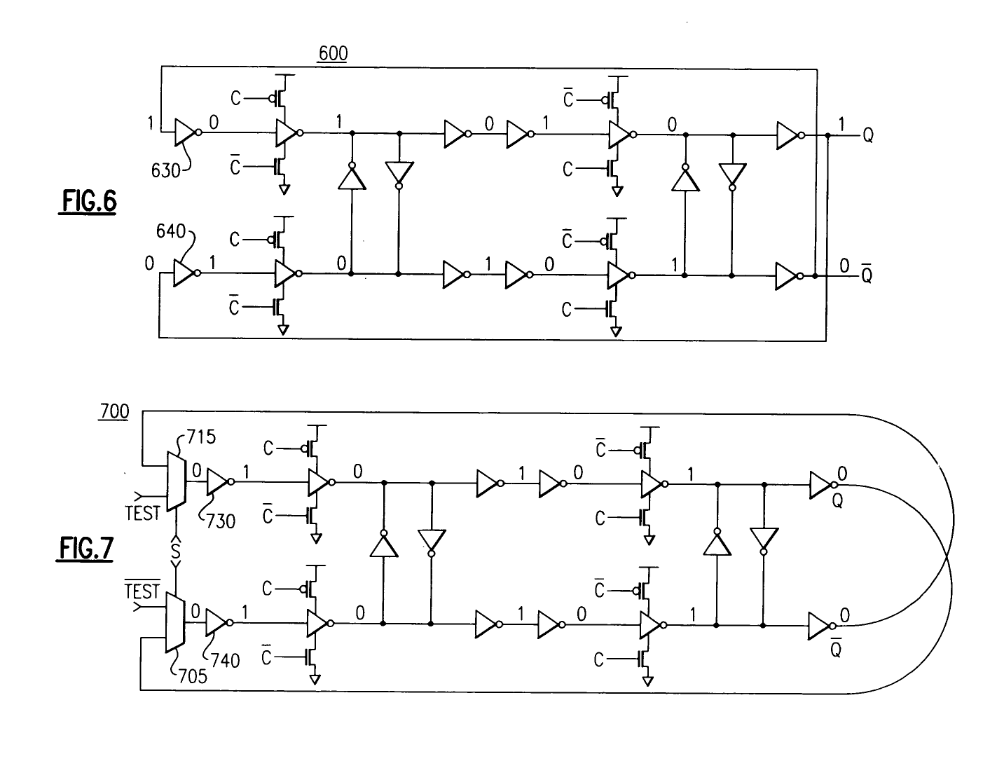

FIG. 4 illustrates a variation of the MS flip-flop 200 shown and described above with respect to FIG. 3. In the case shown in FIG. 4, the MS flip-flop 400 need only receive a single-ended input signal D. However, like the MS flip-flop 200 (FIG. 3), it produces differential rail-to-rail output signals Q and /Q. As shown in FIG. 4, the MS flip-flop 400 includes a slave latch 100B which is the same as the slave latch described above with respect to the MS flip-flop 200 (FIG. 3).

MS flip-flop 400 varies from MS flip-flop 200 (FIG. 3) in the structure and operation of the master latch 300A. As shown in FIG. 4, the differential clock signal pair C and /C times the operation of an inverter 330 at the front end of the master latch such that its output transitions at the falling edge of the true clock signal C. The differential clock signal pair C and /C also times the operation of the inverter 304 of the cross-coupled inverters 302, 304. Inverter 304 is timed by the differential clock signal pair such that it becomes active at the rising edge of the true clock signal C to maintain the state of nodes 310 and 320 once the true clock signal transitions to the high state. By virtue of the cross-coupled arrangement between inverters 302 and 304, the operation of inverter 304 maintains the logic states of the first and second nodes 310, 320 of the master latch after the rising edge of the true clock signal.

The output signals Q and /Q of the slave latch 100B then transition to their latched states following the rising edge of the true clock signal once the signals from the latched nodes 310, 320 are transferred through the inverters 130B, 140B and 132B, 142B. Specifically, the logic state at node 310 of the master latch 300A is applied directly to inverter 140B of the slave latch 100B. The signal appearing at node 320 of the master latch 300A is applied to inverter 130B of the slave latch. At the rising edge of the true clock signal, the logic states which appear then at nodes 310, 320, having been inverted by inverters 130B, 140B, are inverted once more by operation of inverters 132B and 142B and are then latched by the cross-coupled devices 102B and 104B of the slave latch. The output signals Q and /Q will then transition to respective logic states.

FIG. 5 illustrates a further variation in which the MS flip-flop 400 (FIG. 4) is incorporated into a single-ended to differential rail-to-rail CMOS clock divider circuit 500. Here, the clock divider circuit 500 varies from the MS flip-flop 400 in that the /Q (complementary) output signal of the flip-flop 400 is provided as a feedback input at the D input of the initial inverter 530 of the flip-flop. By virtue of this arrangement, the complementary (/Q) output signal transitions from the high logic state to the low logic state at the rising edge of the true clock signal C. The /Q output signal remains at the low logic state for one full clock cycle, then transitions to the high logic state and remains at the high logic state for the next full clock cycle. Simultaneously, the true (Q) output signal transitions from the low logic state to the high logic state at the rising edge of the true clock signal C. The Q output signal remains at the high logic state for one full clock cycle, then transitions to the low logic state and remains at the low logic state for the next full clock cycle.

In this way, each of the output signals Q and /Q transition to their respective different states only after one full cycle of the differential clock signal has passed after the state of that output signal /Q last changed. Stated another way, the differential output signals Q and /Q are a version of the differential clock signal pair C and /C which is divided in frequency to one-half of its original frequency. Ultimately, the clock divider circuit 500 outputs a divided down differential clock signal pair Q and /Q, in which both output signals Q and /Q transition to different logic states simultaneously.

FIG. 6 illustrates a differential clock signal divider circuit 600 which is similar in operation to the above-described clock divider circuit 500 (FIG. 5). However, clock divider circuit 600 incorporates the differential MS flip-flop 200 (FIG. 3) instead. The output signals Q and /Q of the flip-flop are provided as feedback inputs to the initial inverters 640, 630 at the front end of the flip-flop, respectively. As in the case of clock divider circuit 500 (FIG. 5), the true and complementary output signals Q and /Q of the clock divider circuit 600 transition between their respective logic states at intervals of one full clock cycle. In this way, the Q and /Q output signals of the clock divider circuit have a frequency which is one half the frequency of the differential clock signal pair C and /C.

FIG. 7 illustrates a modified clock divider circuit 700 which is similar to the clock divider circuit 600 (FIG. 6). In this case, multiplexors 705, 715 are added to the clock divider circuit at the front end. The purpose of the multiplexors is to permit a pair of differential signals (TEST and /TEST) having known states to be selectively applied as input to the clock divider circuit 700. A selection signal S, when enabled, applies the differential signals TEST, /TEST to the input inverters 730, 740 of the circuit. In this way, the TEST, /TEST signals having known states can be applied to the clock divider for purposes of testing its function and performance.

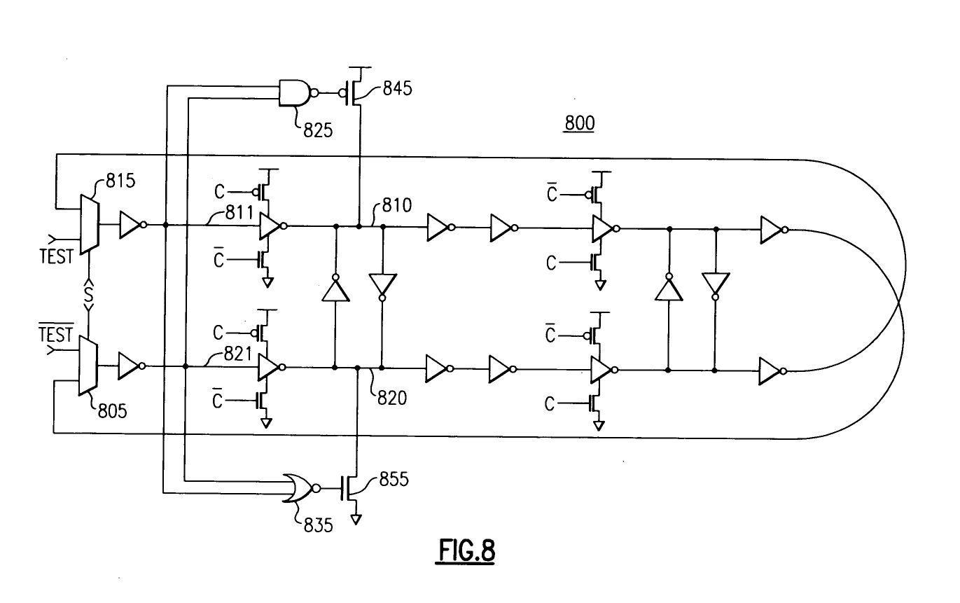

FIG. 8 illustrates yet another modified clock divider circuit 800, which is similar to the clock divider circuit 700 (FIG. 7). In this case, the clock divider circuit 800 includes two additional logic gates, a NAND gate 825 and a NOR gate 835. The clock divider circuit 800 additionally includes one each of a pMOS pull-up device 845 and an nMOS pull-down device 855. The purpose of the added logic gates and the pull-up and pull-down devices is to prevent the clock divider circuit 800 from becoming stuck in the same state. Without the added devices, it is possible that the nodes 810 and 820 of the clock divider circuit 800 might both become stuck at the same low logic state or stuck at the same high logic state, due to the multiplexors 805, 815 passing one of the Q and /Q inputs faster than the other. The clock divider circuit then would not function, remaining stuck in the same state.

By operation of the added logic gates and devices, the nodes 810, 820 can no longer become stuck in the same state. For example, if both of the nodes 810, 820 have the same low logic state, then nodes 811 and 821 each have high logic state. In that case, the output of the NAND gate 825 will fall to a low logic state. Pull-up device 845 will then be activated, causing node 810 to rise to the high logic state. On the other hand, when both of the nodes 810, 820 have the same high logic state, nodes 811 and 821 each have low logic state. In that case, the output of the NOR gate will rise to a high logic state. Pull-down device 855 will then be activated, causing node 820 to fall to the low logic state.

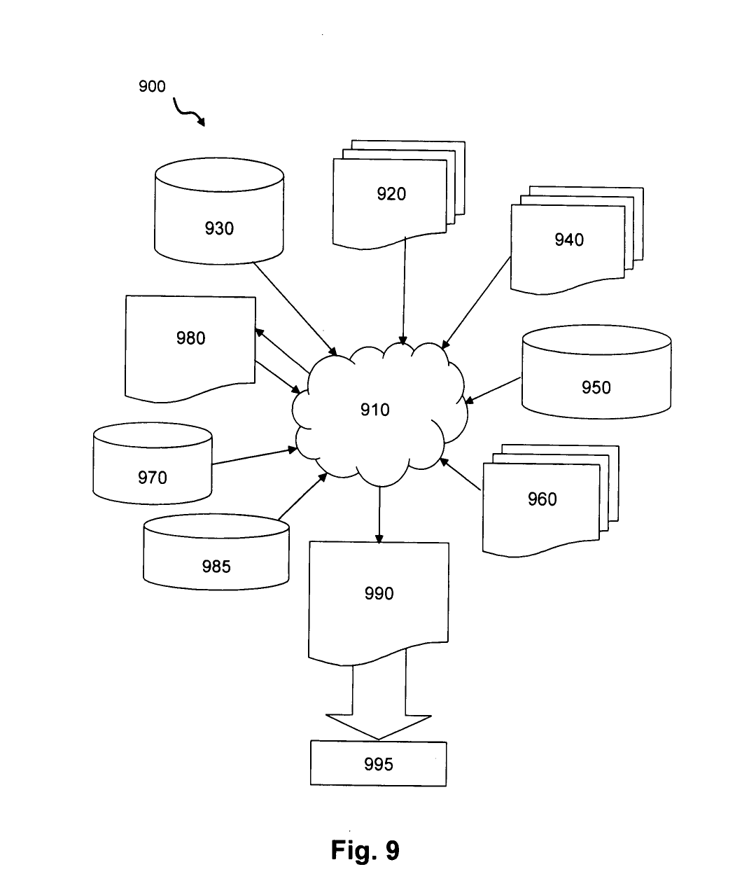

FIG. 9 shows a block diagram of an example design flow 900. Design flow 900 may vary depending on the type of IC being designed. For example, a design flow 900 for building an application specific IC (ASIC) may differ from a design flow 900 for designing a standard component. Design structure 920 is preferably an input to a design process 910 and may come from an IP provider, a core developer, or other design company or may be generated by the operator of the design flow, or from other sources. Design structure 920 comprises a CMOS latch 100A and 100B or master-slave flip-flop (FIG. 3) in the form of schematics or HDL, a hardware-description language (e.g., Verilog, VHDL, C, etc.). Design structure 920 may be contained on one or more machine readable medium. For example, design structure 920 may be a text file or a graphical representation of a CMOS latch 100A and 100B. Design process 910 preferably synthesizes (or translates) CMOS latch into a netlist 980, where netlist 980 is, for example, a list of wires, transistors, logic gates, control circuits, I/O, models, etc. that describes the connections to other elements and circuits in an integrated circuit design and recorded on at least one of machine readable medium. This may be an iterative process in which netlist 980 is resynthesized one or more times depending on design specifications and parameters for the circuit.

Design process 910 may include using a variety of inputs; for example, inputs from library elements 930 which may house a set of commonly used elements, circuits, and devices, including models, layouts, and symbolic representations, for a given manufacturing technology (e.g., different technology nodes, 32 nm, 45 nm, 90 nm, etc.), design specifications 940, characterization data 950, verification data 960, design rules 970, and test data files 985 (which may include test patterns and other testing information). Design process 910 may further include, for example, standard circuit design processes such as timing analysis, verification, design rule checking, place and route operations, etc. One of ordinary skill in the art of integrated circuit design can appreciate the extent of possible electronic design automation tools and applications used in design process 910 without deviating from the scope and spirit of the invention. The design structure of the invention is not limited to any specific design flow.

Design process 910 preferably translates an embodiment of the invention as shown in [fill in figure or figures that represent the design], along with any additional integrated circuit design or data (if applicable), into a second design structure 990. Design structure 990 resides on a storage medium in a data format used for the exchange of layout data of integrated circuits (e.g. information stored in a GDSII (GDS2), GL1, OASIS, or any other suitable format for storing such design structures). Design structure 990 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIGS. 2 through 8. Design structure 990 may then proceed to a stage 995 where, for example, design structure 990: proceeds to tape-out, is released to manufacturing, is released to a mask house, is sent to another design house, is sent back to the customer, etc. The design structure and its elements as described above and the operations they perform can be combined and used in various combinations without limitation.

While the invention has been described in accordance with certain preferred embodiments thereof, many modifications and enhancements can be made thereto without departing from the true scope and spirit of the invention, which is limited only by the claims appended below.

What is claimed is:

1. A design structure embodied in a machine-readable medium used in a design process, the design structure comprising:
a complementary metal oxide semiconductor (“CMOS”) rail-to-rail differential latch including:
a plurality of cross-coupled devices serving to pull first and second nodes of said latch to opposite rail-to-rail voltages;
first and second output isolating elements having inputs coupled to said first and second nodes, said first and second output isolating elements being operable to output versions of said opposite rail-to-rail voltages as a true output and a complementary output of said latch, said true output having a rising edge occurring simultaneously with a falling edge of said complementary output and said complementary output having a rising edge occurring simultaneously with a falling edge of said true output; and
first and second input isolating elements versions of input signals to said first and second nodes.

2. The design structure as claimed in claim 1, wherein each of the first and second output isolating elements includes a CMOS inverter and each of the first and second input isolating elements includes a CMOS inverter.

3. The design structure as claimed in claim 2, wherein each of the first and second input isolating elements includes a timing circuit operable to activate the respective CMOS inverter at an edge of a clock signal and the timing circuit of each of the first and second input isolating elements accepts a differential clock signal pair including a true clock signal and a complementary clock signal, the timing circuit being operable in response to the edges of the differential clock signal pair.

4. The design structure having a master-slave (“MS”) CMOS rail-to-rail differential flip-flop including a master one of the CMOS differential latch claimed in claim 1 and a slave one of the CMOS differential latch claimed in claim 1 having inputs connected to receive versions of the true and complementary outputs of the master one of the CMOS differential latch, wherein external outputs of said master-slave CMOS differential latch include said true and complementary outputs of the slave one of the CMOS differential latch.

5. The design structure as claimed in claim 4, wherein each of the first and second input isolating elements of the master latch includes a timing circuit operable to activate the respective CMOS inverter at a falling edge of a clock signal and each of the first and second input isolating elements of the slave latch includes a timing circuit operable to activate the respective CMOS inverter at a rising edge of a clock signal, each timing circuit being activatable in response to edges of a differential clock signal pair including a true clock signal and a complementary clock signal.

6. The design structure having a master-slave (“MS”) CMOS single-ended to differential rail-to-rail flip-flop including a CMOS latch as claimed in claim 1, further comprising a CMOS single-ended to differential master latch connected to apply true and complementary outputs to inputs of said CMOS latch.

7. The design structure having the MS. CMOS flip-flop as claimed in claim 6, further comprising:
a third input isolating element coupled to receive a single-ended logic input; and
a complementary signal generating circuit having an input coupled to a single-ended output of said third input isolating element, said complementary signal generating circuit being operable to generate said true and complementary outputs of said CMOS master latch from an output of said third input isolating element.

8. The design structure having the MS CMOS single-ended to differential rail-to-rail flip-flop as claimed in claim 7, wherein each of said complementary signal generating circuit and said first and second input isolating elements includes a timing circuit operable to activate the respective CMOS inverter at an edge of a clock signal.

9. The design structure having a CMOS rail-to-rail differential clock divider circuit operable to output true and complementary differential rail-to-rail output signals divided down in frequency from true and complementary differential input clock signals, said clock divider circuit including the MS CMOS flip-flop as claimed in claim 6, wherein said true and complementary outputs of said MS CMOS flip-flop are coupled as feedback to said inputs of said first and second input isolating elements of said master latch to cause said true and complementary outputs of said CMOS differential clock divider circuit to toggle; and said differential clock divider circuit includes a plurality of first timing devices and a plurality of second timing devices, said first timing devices being operable to time operation of said master latch on a falling edge of a true clock signal and said second timing devices being operable to time operation of said slave latch on a rising edge of a complementary clock signal.

10. The design structure as claimed in claim 9, further comprising a latch-up prevention circuit and wherein said latch-up prevention circuit includes a first logic gate having inputs coupled to receive versions of input signals applied to said master latch and an output coupled to one of said first or second nodes of said master latch, a second logic gate having inputs coupled to receive the versions of the input signals applied to said master latch and an output coupled to the other one of said first or second nodes of said master latch, said first logic gate being operable to force the state of said one of said first and second nodes when both of the versions of the input signals are logic high, and said second logic gate being operable to force the state of said another one of said first and second nodes when neither of the versions of the input signals are logic high.
